(19) United States
(12) Patent Application Publication
(10) Pub. No.: US 2026/0247770 A1
(43) Pub. Date: Aug. 20, 2026

(54) METHOD OF MANUFACTURING MICROSTRUCTURE ARRAY AND MICRO LIGHT-EMITTING DIODES AND METHOD OF MANUFACTURING THE SAME AND DISPLAY DEVICE

(71) Applicant: UIF (University Industry Foundation), Yonsei University, Seoul (KR)

(72) Inventors: Jae-Min Myoung, Goyang-si (KR); Wooyoung Shim, Seoul (KR); JiHun Yeom, Seoul (KR); Min Seong Kim, Gwangmyeong-si (KR); Jae Youn Jeong, Seoul (KR)

(21) Appl. No.: 19/359,708

(22) Filed: Oct. 16, 2025

(30) Foreign Application Priority Data
Feb. 19, 2025 (KR) 10-2025-0021697

(51) Int. Cl. H10H 29/03

(52) U.S. Cl. CPC H10H 29/03

(57) ABSTRACT

Disclosed are a method for manufacturing a microstructure array, a micro light-emitting diode, and a manufacturing method thereof, and a display device, the method for manufacturing a microstructure array which includes: forming a microstructure array in which a plurality of microstructures including nanocrystals are arranged on a first substrate, contacting a second substrate having a higher surface energy than the first substrate with the microstructure array to pick up the microstructure array from the first substrate, and transferring the microstructure array from the second substrate to a third substrate having a higher surface energy than the second substrate.

### CROSS-REFERENCE TO RELATED APPLICATION

This application claims priority to Korean Patent Application No. 10-2025-0021697, filed on Feb. 19, 2025, and all the benefits accruing therefrom under 35 U.S.C. § 119, the content of which in its entirety is herein incorporated by reference.

### BACKGROUND

### 1. Field

The present disclosure relates to a method of manufacturing a microstructure array, a micro light-emitting diode, a method of manufacturing the same, and a display device.

### 2. Description of the Related Art

In line with the recent trend toward lighter and thinner display devices, research is being conducted on light-emitting devices using self-luminous nano-sized light-emitters, such as quantum dot light-emitting diodes or perovskite light-emitting diodes.

### SUMMARY

Although nano-sized light-emitters such as quantum dots or perovskites are attracting attention as key materials for light-emitting devices based on their high color purity and excellent luminescent properties, their chemical vulnerability may limit the application of patterning processes using chemical solutions such as photolithography.

An embodiment provides a method of manufacturing a microstructure array capable of forming a micropattern without exposure to a chemical solution.

Another embodiment provides a method of manufacturing a micro light-emitting diode capable of forming a micropattern without exposure to a chemical solution.

Another embodiment provides a micro light-emitting diode manufactured by the method.

Another embodiment provides a display device including the micro light-emitting diode.

According to an embodiment, a method of manufacturing a microstructure array includes: forming a microstructure array in which a plurality of microstructures including nanocrystals are arranged on a first substrate, contacting a second substrate having a higher surface energy than the first substrate with the microstructure array to pick up the microstructure array from the first substrate, and transferring the microstructure array from the second substrate onto a third substrate having a higher surface energy than the second substrate.

The method may further include performing oxygen plasma treatment on the surface of the second substrate before contacting the second substrate with the microstructure array.

A surface contact angle of the second substrate subjected to the oxygen plasma treatment may be 0 to about 20 degrees.

The method may further include performing a surface energy reduction treatment on the first substrate before contacting the second substrate with the microstructure array.

A surface contact angle of the first substrate subjected to the surface energy reduction treatment may be about 25 degrees to about 150 degrees.

The method may further include performing a surface energy reduction treatment on the second substrate before transferring the microstructure array onto the third substrate.

A surface contact angle of the second substrate subjected to the surface energy reduction treatment may be about 25 to about 150 degrees.

The first substrate and the second substrate may each include polydimethylsiloxane.

The nanocrystals may include perovskite nanocrystals, quantum dot nanocrystals, or a combination thereof.

The forming of the microstructure array on the first substrate may include preparing a mold having a concave micropattern array in which a plurality of concave micropatterns are arranged, preparing a perovskite precursor solution including a perovskite precursor, performing the surface of the first substrate with oxygen plasma treatment, applying the perovskite precursor solution onto the first substrate subjected to oxygen plasma treatment, placing the mold on the perovskite precursor solution to confine the perovskite precursor solution in the plurality of concave micropatterns, crystallizing the perovskite precursor in the plurality of concave micropatterns to obtain a plurality of microstructures including perovskite nanocrystals, and removing the mold to form a microstructure array in which the plurality of microstructures are arranged.

The method may further include forming an electrode or a stack of the electrode and a charge auxiliary layer having a higher surface energy than the second substrate on the third substrate, before the transferring of the microstructure array onto the third substrate, and the microstructure array may be transferred onto the electrode or the stack of the electrode and the charge auxiliary layer.

The microstructure array may be configured to emit light in at least one wavelength region among a red wavelength region, a green wavelength region, and a blue wavelength region.

According to another embodiment, a method of manufacturing a micro light-emitting diode includes preparing a third substrate on which a first electrode or a stack of the first electrode and a first charge auxiliary layer is formed, transferring a microstructure array onto the first electrode or the stack of the first electrode and the first charge auxiliary layer, and forming a second electrode or a stack of the second electrode and a second charge auxiliary layer on the microstructure array, wherein the transferring of the microstructure array may include transferring a first microstructure array in which a plurality of first microstructures including nanocrystals configured to emit light of a first wavelength region, which is one of a red wavelength region, a green wavelength region, and a blue wavelength region, are arranged, transferring a second microstructure array in which a plurality of second microstructures including nanocrystals configured to emit light of a second wavelength region, which is one of a red wavelength region, a green wavelength region, and a blue wavelength region, are arranged, and transferring a third microstructure array in which a plurality of third microstructures including nanocrystals configured to emit light of a third wavelength region, which is one of a red wavelength region, a green wavelength region, and a blue wavelength region, are arranged, at least one of transferring the first, second, and third microstructure arrays includes forming a microstructure array in which a plurality of microstructures including nanocrystals are arranged on a first substrate, contacting a second substrate having a higher surface energy than the first substrate with the microstructure array to pick up the microstructure array from the first substrate, and transferring the microstructure array from the second substrate onto the first electrode having a higher surface energy than the second substrate or the stack of the first electrode and the first charge auxiliary layer.

According to another embodiment, a micro light-emitting diode array manufactured by the method is provided.

According to another embodiment, a display device including the micro light-emitting diode array is provided.

Microstructure arrays may be effectively manufactured without exposure to chemical solutions.

### BRIEF DESCRIPTION OF THE DRAWINGS

FIGS. 1 to 4 are schematic views showing an example of a method of manufacturing a microstructure array according to an embodiment,

FIGS. 5 to 8 are schematic views sequentially showing an example of a method of manufacturing the microstructure array of FIG. 1,

FIGS. 9A to 90, 10A to 10C, and 11 to 16 are schematic views sequentially showing another example of a method of manufacturing a microstructure array according to an embodiment,

FIG. 17 is a schematic view showing an example of an arrangement of sub-pixels of a micro light-emitting diode according to an embodiment,

FIG. 18 is a schematic view showing a micro light-emitting diode according to an embodiment,

FIG. 19 is a cross-sectional view showing one sub-pixel of the micro light-emitting diode of FIG. 18,

FIG. 20 is a graph showing the change in contact angle over time after oxygen plasma treatment on the first substrate and the second substrate used in the manufacture of the microstructure array according to Example 1, FIG. 21A is a photograph showing the photoluminescence of the microstructure array formed on the first substrate in Example 1,

FIG. 21B is a photograph showing the photoluminescence of the microstructure array transferred onto the third substrate in Example 1,

FIG. 22A is a photograph showing the photoluminescence of the microstructure array formed on the first substrate in Example 2,

FIG. 22B is a photograph showing the photoluminescence of the microstructure array transferred onto the third substrate in Example 2, FIG. 23A is a photograph showing the photoluminescence of the microstructure array formed on the first substrate in Example 3,

FIG. 23B is a photograph showing the photoluminescence of the microstructure array transferred onto the third substrate in Example 3, FIG. 24 shows emission spectra of the microstructure arrays according to Examples 1 to 3, and

FIG. 25 is a photograph showing the photoluminescence of the green, red, and blue microstructure arrays transferred onto the third substrate in Example 4.

### DETAILED DESCRIPTION

Hereinafter, specific embodiments will be described in detail so that those of ordinary skill in the art can easily implement them. However, this disclosure may be embodied in many different forms and is not construed as limited to the example embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, the term ‘combination’ may include mixture and a stacked structure of two or more.

Hereinafter, a ‘precursor’ may be a reactant or a previous material used to obtain a final product, and may include a monomer, an oligomer, and/or a pre-polymer.

Hereinafter, the dimension may be a width, a length and/or a thickness, and the width and length may be sizes extending in different directions (e.g., vertically) in the same plane, and the thickness may be a size extending in a direction perpendicular to the width and length, respectively. For example, in the case of a structure formed on a substrate, the size extending in the in-plane direction of the substrate (x and y directions) may be the width and length, respectively, and the size extending in the thickness direction of the substrate (z direction) may be the thickness.

An example of a method of manufacturing a microstructure array according to an embodiment is described with reference to the drawings.

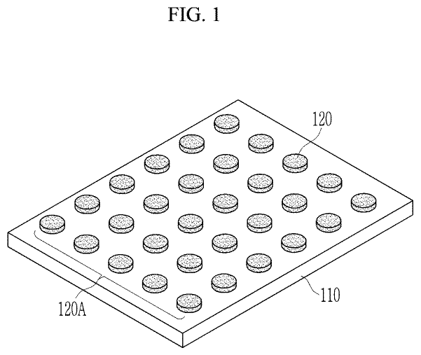

FIGS. 1 to 4 are schematic views showing an example of a method for manufacturing a microstructure array according to embodiments.

A method of manufacturing a microstructure array according to an embodiment may include forming a microstructure array 120A in which a plurality of microstructures 120 including nanocrystals are arranged on a first substrate 110, contacting a second substrate 210 with the microstructure array 120A in which the plurality of microstructures 120 are arranged to pick up the microstructure array 120A from the first substrate 110, and transferring the microstructure array 120A from the second substrate 210 onto a third substrate 310.

Referring to FIG. 1, the microstructure array 120A is formed in which the plurality of microstructures 120 are arranged on a first substrate 110. Each microstructure 120 may be a light-emitter including nanocrystals, and the plurality of microstructures 120 may be arranged along rows and/or columns to form a microstructure array 120A. However, the present disclosure is not limited thereto, and a plurality of microstructures 120 may be randomly arranged on the first substrate 110.

The first substrate 110 may be a substrate for forming a pattern defining the plurality of microstructures 120 and at the same time a substrate for growing crystals for growing nanocrystals in the microstructures 120, and may be a donor substrate that provides the microstructure array 120A in which the plurality of microstructures 120 are arranged to a third substrate 310 described later.

The first substrate 110 may include an elastic silicone material, for example, polydimethylsiloxane (PDMS). PDMS may generally have a hydrophobic surface, and therefore, PDMS without any surface treatment may have a relatively low surface energy and a relatively high contact angle (water contact angle) of about 25 to about 150 degrees.

For example, in the forming of the microstructure array 120A, the surface of the first substrate 110 may be modified to be hydrophilic. A hydrophilically modified PDMS surface may have, for example, a relatively high surface energy and a relatively low contact angle (water contact angle) of 0 to about 20 degrees. Afterwards, the PDMS surface may be recovered to hydrophobicity again by surface energy reduction treatment (including leaving it for a predetermined time). The surface energy reduction treatment may be, for example, left it for about 20 minutes or more and/or annealing, as described later.

For example, modification of the PDMS surface to hydrophilicity may be performed by plasma, for example, by oxygen plasma (O₂ plasma). The O₂ plasma may modify the PDMS surface to be strongly hydrophilic by replacing the methyl groups (—CH₃) on the PDMS surface with —O and/or —OH groups. The oxygen plasma treatment may be performed, for example, at about 5 W to about 80 W for about 30 seconds to about 30 minutes, or within the above range, at about 10 W to about 50 W for about 1 minute to about 20 minutes, or at about 10 W to about 30 W for about 1 minute to about 10 minutes, but is not limited thereto.

The plurality of microstructures 120 may be formed from a precursor solution using a polar solvent as described later, and the precursor solution using the polar solvent may adhere to a hydrophilically modified PDMS surface with high wettability and grow into nanocrystals with relatively uniform size. The growth of nanocrystals and the formation of the plurality of microstructures 120 may be performed simultaneously, as described later.

The plurality of microstructures 120 may be island-shaped light-emitters having a size (dimension) of several to several tens of micrometers, and may have a planar shape of, for example, a polygon such as a square, a rectangle, a hexagon or an octagon, a circle or an ellipse, but are not limited thereto. Herein, the size may be width and/or length, and when the planar shape of the microstructure 120 is circular or elliptical, the width may be diameter or long diameter.

The size (dimension) of the microstructure 120 may be, for example, less than about 100 μm, within the above range, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 15 μm, less than or equal to about 10 μm, or less than or equal to about 7 μm, and within the above range, greater than or equal to about 0.01 μm and less than about 100 μm, about 0.01 μm to about 80 μm, about 0.01 μm to about 70 μm, about 0.01 μm to about 60 μm, about 0.01 μm to about 50 μm, about 0.01 μm to about 40 μm, about 0.01 μm to about 30 μm, about 0.01 μm to about 20 μm, about 0.01 μm to about 15 μm, about 0.01 μm to about 10 μm, about 0.01 μm to about 7 μm, greater than or equal to about 0.1 μm and less than about 100 μm, about 0.1 μm to about 80 μm, about 0.1 μm to about 70 μm, about 0.1 μm to about 60 μm, about 0.1 μm to about 50 μm, about 0.1 μm to about 40 μm, about 0.1 μm to about 30 μm, about 0.1 μm to about 20 μm, about 0.1 μm to about 15 μm, about 0.1 μm to about 10 μm or about 0.1 μm to about 7 μm.

For example, the microstructure 120 may be an island-shaped light-emitter having a width and length of less than or equal to about 80 μm. For example, the microstructure 120 may be an island-shaped light-emitter having a width and length of less than or equal to about 50 μm. For example, the microstructure 120 may be an island-shaped light-emitter having a width and length of less than or equal to about 30 μm. For example, the microstructure 120 may be an island-shaped light-emitter having a width and length of less than or equal to about 20 μm. For example, the microstructure 120 may be an island-shaped light-emitter having a width and length of less than or equal to about 10 μm.

The microstructure 120 may be configured to emit light of a predetermined wavelength region in the visible light wavelength region, and for example, may be configured to emit light of any one of a red wavelength region, a green wavelength region, and a blue wavelength region. The red wavelength region may have a peak emission wavelength (λ_{peak,R}) of, for example, more than about 600 nm and less than or equal to about 750 nm, the green wavelength region may have a peak emission wavelength (λ_{peak,G}) of, for example, about 500 nm to about 600 nm, and the blue wavelength region may have a peak emission wavelength (λ_{peak,B}) of, for example, greater than or equal to about 380 nm and less than about 500 nm.

The microstructure 120 may include nanocrystals, which may include, for example, perovskite nanocrystals, quantum dot nanocrystals, or a combination thereof. For example, the perovskite nanocrystals and/or quantum dot nanocrystals may be perovskite nanocrystals and/or quantum dot nanocrystals synthesized from a precursor solution including a polar solvent.

As an example, the microstructure 120 may include perovskite nanocrystals. The perovskite nanocrystals are semiconductor crystals configured to emit light in the visible light wavelength region, for example, light in one of the red wavelength region, the green wavelength region, and the blue wavelength region. The red wavelength region may have a peak emission wavelength (λ_{peak,R}) of, for example, more than about 600 nm and less than or equal to about 750 nm, the green wavelength region may have a peak emission wavelength (λ_{peak,G}) of, for example, about 500 nm to about 600 nm, and the blue wavelength region may have a peak emission wavelength (λ_{peak,B}) of, for example, greater than or equal to about 380 nm and less than about 500 nm.

The perovskite nanocrystals may have a sub-micrometer crystal size, for example, the average crystal size of the perovskite nanocrystals may be less than or equal to about 800 nm, less than or equal to about 600 nm, less than or equal to about 500 nm, less than or equal to about 300 nm, less than or equal to about 200 nm, less than or equal to about 150 nm, less than or equal to about 100 nm, less than or equal to about 80 nm, or less than or equal to about 50 nm, and within the above range, may be about 2 nm to about 800 nm, about 2 nm to about 600 nm, about 2 nm to about 500 nm, about 2 nm to about 300 nm, about 2 nm to about 200 nm, from 2 nm to 150 nm, about 2 nm to about 100 nm, about 2 nm to about 80 nm, or about 2 nm to about 50 nm. Defects in the crystal may be reduced due to the crystal size of the sub-micrometer to prevent a decrease in luminous efficiency at room temperature.

The perovskite nanocrystals may have a relatively uniform crystal size. For example, the deviation of the crystal size of the perovskite nanocrystals may be less than or equal to about 50%, less than or equal to about 40%, less than or equal to about 30%, less than or equal to about 20%, or less than or equal to about 10% of the average crystal size.

The perovskite nanocrystals may have a crystal structure including cations and anions, for example, a layered structure or a non-layered structure. The perovskite nanocrystals may have a crystal structure represented by, for example, ABX₃, A₂BX₄, ABX₄, Aₙ₋₁BₙX₃ₙ₊₁, or L₂Aₙ₋₁BₙX₃ₙ₊₁ (0n≤1), but is not limited thereto. Herein, A may be a monovalent inorganic cation such as Li⁺, Na⁺, K⁺, Rb⁺, and Cs⁺; a monovalent organic cation such as an organic ammonium cation and an organic amino cation; or a combination thereof, and B may be a metal cation including a transition metal, a rare earth metal, an alkaline earth metal or a combination thereof such as Pb²⁺, Sn²⁺, Ge²⁺, Ga²⁺, In²⁺, Al²⁺, Sb²⁺, Bi²⁺, and Po²⁺, X may be an oxygen ion or a halide anion such as F⁻, Cl⁻, Br⁻, or I⁻, and L may be an aliphatic or aromatic ammonium cation or an aliphatic or aromatic amino cation which is different from A. The organic ammonium cation or organic amino cation may be, for example, methylammonium, formamidinium, or phenylammonium, but is not limited thereto. The aliphatic or aromatic ammonium cation or the aliphatic or aromatic amino cation may be, for example, n-butyl ammonium, 2-phenylmethyl ammonium, or 2-phenylethyl ammonium, but is not limited thereto.

For example, the perovskite nanocrystals may be halide perovskite nanocrystals including halide anions.

For example, the perovskite nanocrystals may be organic-inorganic hybrid perovskite nanocrystals including organic cations and metal cations.

For example, the perovskite nanocrystals may be CH₃NH₃PbBr₃, CH₃NH₃PbI₃, CH₃NH₃SnBr₃, CH₃NH₃SnI₃, CH₃NH₃Sn₁₋ₓPbₓBr₃, CH₃NH₃Sn₁₋ₓPbₓI₃, HC(NH₂)₂PbI₃, HC(NH₂)₂SnI₃, (C₄H₉NH₃)₂PbBr₄, (C₆H₅CH₂NH₃)₂PbBr₄, (C₆H₅CH₂NH₃)₂PbI₄, (C₆H₅C₂H₄NH₃)₂PbBr₄, (C₆H₁₃NH₃)₂ (CH₃NH₃)ₙ₋₁PbₙI₃ₙ₊₁, or a combination thereof, but are not limited thereto.

For example, the microstructure 120 may optionally further include a hydrophilic polymer and/or an ionic liquid, and a ligand bound or coordinated to the surface of the perovskite nanocrystals, in addition to the perovskite nanocrystals.

The hydrophilic polymer may surround the perovskite nanocrystals and may be a chain-like or cross-linked polymer. The hydrophilic polymer may further reduce the surface energy between the perovskite precursor solution and the first substrate 110 in the forming of the microstructure 120, thereby further increasing the wettability of the perovskite precursor solution on the first substrate 110, and enabling the microstructure 120 to be formed into a desired shape and size according to the concave micropattern of the mold in the forming of the microstructure 120 using the mold described later. Additionally, the hydrophilic polymer may prevent degradation by oxygen and/or moisture by reducing the exposure of the perovskite nanocrystals in the microstructure 120 to oxygen and/or moisture in the air.

The hydrophilic polymer may include polyvinylpyrrolidone (PVP), polyethylenimine (PEI), polyacrylamide (PAM), poly (meta) acrylate, polyvinylalcohol (PVA), polyethylene glycol, polyethyleneoxide, polyoxazoline, a derivative thereof, or a copolymer thereof, but is not limited thereto.

The ionic liquid may increase stability of the perovskite nanocrystals and may be 1-butyl-3-methylimidazolium tetrafluoroborate (BMIMBF₄), poly(2-acrylamino-2-methylpropane sulfonic acid), poly(ethylene oxide), 1-butyl-3-methylimidazolium bis(trifluoromethylsulfonyl)imide (BMIMTFSI), or a combination thereof, but is not limited thereto.

The hydrophilic polymer and/or ionic liquid may be included, for example, in the same amount as the perovskite nanocrystals or less amount than the perovskite nanocrystals. For example, the hydrophilic polymer and/or ionic liquid may be included in an amount of about 0.01 to about 100 parts by weight based on 100 parts by weight of the perovskite nanocrystals, within the above range, about 0.01 to about 80 parts by weight, about 0.01 to about 50 parts by weight, about 0.01 to about 30 parts by weight or 0.01 to about 20 parts by weight based on 100 parts by weight of the perovskite nanocrystals.

The ligand may be bound or coordinated to the surface of the perovskite nanocrystals. The ligand may be, for example, an organic ligand, and may be derived from, for example, aliphatic hydrocarbons and/or aromatic hydrocarbons. The ligand may be for example derived from RCOOH, RNH₂, R₂NH, R₃N, RSH, RH₂PO, R₂HPO, R₃PO, RH₂P, R₂HP, R₃P, ROH, RCOOR, RPO(OH)₂, RPOOH, RHPOOH, or R₂POOH (wherein, R is independently a substituted or unsubstituted C1 to C40 aliphatic hydrocarbon, a substituted or unsubstituted C6 to C40 aromatic hydrocarbon, or a combination thereof). The ligand may be, for example, derived from methane thiol, ethane thiol, propane thiol, butane thiol, pentane thiol, hexane thiol, octane thiol, dodecane thiol, hexadecane thiol, octadecane thiol, benzyl thiol; methane amine, ethane amine, propane amine, butyl amine, pentyl amine, hexyl amine, octyl amine, dodecyl amine, hexadecyl amine, octadecyl amine, dimethyl amine, diethyl amine, dipropyl amine, oleyl amine; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid; phosphine such as a substituted or unsubstituted methyl phosphine (e.g., trimethyl phosphine, methyldiphenyl phosphine, etc.), a substituted or unsubstituted ethyl phosphine (e.g., triethyl phosphine, ethyldiphenyl phosphine, etc.), a substituted or unsubstituted propyl phosphine, a substituted or unsubstituted butyl phosphine, a substituted or unsubstituted pentyl phosphine, a substituted or unsubstituted octylphosphine (e.g., trioctylphosphine (TOP)), and the like; phosphine oxide such as a substituted or unsubstituted methyl phosphine oxide (e.g., trimethyl phosphine oxide, methyldiphenyl phosphineoxide, etc.), a substituted or unsubstituted ethyl phosphine oxide (e.g., triethyl phosphine oxide, ethyldiphenyl phosphineoxide, etc.), a substituted or unsubstituted propyl phosphine oxide, a substituted or unsubstituted butyl phosphine oxide, a substituted or unsubstituted octylphosphine oxide (e.g., trioctylphosphineoxide (TOPO), and the like; a diphenyl phosphine, triphenyl phosphine compound or an oxide compound thereof; C2 to C40 phosphonic acid; C2 to C40 phosphinic acid, and the like, but is not limited thereto.

The ligand, as described below, may effectively control crystal growth from a perovskite precursor in the step of forming the microstructure 120, thereby allowing perovskite nanocrystals to relatively uniformly grow with a crystal size of sub-micrometers.

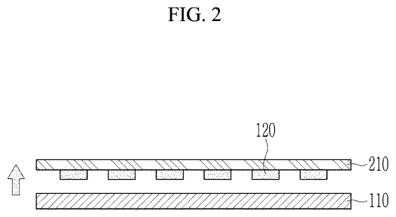

Subsequently, referring to FIG. 2, the second substrate 210 is disposed on the first substrate 110 where the microstructure array 120A is arranged, and then, contact the second substrate 210 with the plurality of microstructures 120 to pick up the microstructure array 120A including the plurality of microstructures 120 from the first substrate 110.

The second substrate 210 may be a transfer substrate for picking up the microstructure array 120A from the first substrate 110 to transfer the microstructure array 120A onto a third substrate 310 described later. The second substrate 210 also may include an elastic silicone material, for example, PDMS. As described above, the PDMS surface may be generally hydrophobic but modified to be hydrophilic by a process such as an oxygen plasma treatment.

In the picking up the plurality of microstructures 120 from the first substrate 110 by contacting the second substrate 210 with the plurality of microstructures 120, the second substrate 210 may have higher surface energy than the first substrate 110. Accordingly, the microstructure array 120A including the plurality of microstructures 120 may be easily separated from the first substrate 110 and adhered to the second substrate 210.

For this purpose, before picking up the microstructure array 120A, the second substrate 210 may be modified to be hydrophilic or made to be more hydrophilic by the oxygen plasma treatment and the like, and simultaneously or separately, the hydrophilically modified surface of the first substrate 110 may be recovered to be hydrophobic.

For example, the second substrate 210 may include hydrophilically modified PDMS, and the hydrophilically modified PDMS may have relatively high surface energy and a relatively low contact angle (water contact angle) of about 0° to about 20°.

For example, to recover hydrophobicity of the surface of the first substrate 110, the first substrate 110 may be allowed to stand until the hydrophilicity may disappear or separately treated with a surface energy reduction treatment. The surface energy reduction treatment may be, for example, annealing, for example, performed at about 50° C. to about 200° C. for about 1 minute to about 60 minutes and within the above range, for about 70° C. to about 150° C. for about 1 minute to about 40 minutes or at about 90° C. to about 110° C. for about 5 minutes to about 15 minutes, but is not limited thereto. A surface contact angle (water contact angle) of the first substrate 110 recovered to be hydrophobic may be about 25° to about 150°.

In this way, as the surface energy of the first substrate 110 and the second substrate 210 may be controlled by the hydrophobic recovery of the surface of the first substrate 110 and the hydrophilic modification of the surface of the second substrate 210, the microstructure array 120A may be easily separated from the first substrate 110 and adhered to the second substrate 210, and thus effectively picked up.

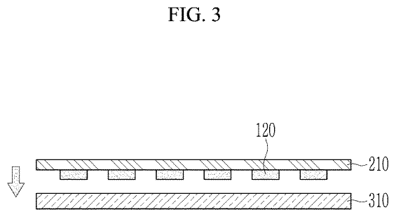

Referring to FIG. 3, the second substrate 210 on which the microstructure array 120A is arranged is disposed to face and contact with the third substrate 310, so that the microstructure array 120A may be transferred from the second substrate 210 to the third substrate 310.

The third substrate 310 may include, for example, an inorganic material such as glass; an organic material such as polycarbonate, polymethyl methacrylate, polyethylene terephthalate, polyethylene naphthalate, polyamide, polyether sulfone or a combination thereof; a metal plate and/or a silicon wafer. The third substrate 310 may be a final substate on which the microstructure array 120A may be disposed, which may be a substrate of a micro light-emitting diode to be described later.

When the microstructure array 120A is transferred from the second substrate 210 to the third substrate 310, the third substrate 310 may have higher surface energy than the second substrate 210, and accordingly, the microstructure array 120A may be easily separated from the second substrate 210 and adhered to the third substrate 310.

For this purpose, the microstructure array 120A that is modified to be hydrophilic may be recovered to be hydrophobic before transferring the microstructure array 120A. For example, to recover the hydrophobicity of the surface of the second substrate 210, the second substrate 210 may be allowed to stand until the hydrophilicity disappears for predetermined time or separately treated with a surface energy reduction treatment such as annealing. The annealing for reducing the surface energy of the second substrate 210 may be performed, for example, at about 25 to about 90° C. for about 5 minutes to about 2 hours, or within the above range, may be performed at about 25 to about 70° C. for about 5 minutes to about 90 minutes or at about 25 to about 50° C. for about 5 minutes to about 60 minutes, but is not limited thereto. The surface energy of the second substrate 210 subjected to hydrophobic recovery may be lowered again and have a surface contact angle (water contact angle) of about 25 degrees to about 150 degrees.

For example, an electrode or a stack of an electrode and a charge auxiliary layer may be formed on the third substrate 310. The electrode may include a conductive metal oxide, such as zinc oxide, indium oxide, tin oxide, indium tin oxide (ITO), indium zinc oxide (IZO) or fluorine-doped tin oxide, or a thin single-layer or multi-layer metal film, and the charge auxiliary layer may be, for example, a hole injection layer, a hole transport layer, an electron blocking layer, an electron injection layer, an electron transport layer, and/or a hole blocking layer. The electrode or the stack of the electrode and the charge auxiliary layer may be formed on the third substrate 310 before transferring the microstructure array 120A onto the third substrate 310, and the surface energy of the electrode or the stack of the electrode and the charge auxiliary layer may be higher than the surface energy of the second substrate 210. For example, the surface contact angle of the electrode or the surface contact angle of the stack of the electrode and the charge auxiliary layer may be, for example, 0 to about 20 degrees, and within the above range may be 0 to about 15 degrees.

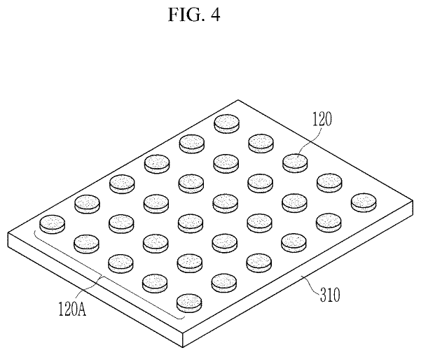

Referring to FIG. 4, the second substrate 210 may be removed to form the microstructure array 120A on the third substrate 310.

As described above, the surface energy of the first substrate 110, which is a substrate for pattern formation, crystal growth and a donor substrate, and the second substrate 210, which is a transfer substrate, may be controlled to effectively pick up and transfer the microstructure array 120A onto the third substrate 310, a final substrate, forming the microstructure array 120A on the third substrate 310 (including an electrode or an electrode/charge auxiliary layer stack) without exposure to a chemical solution. This microstructure array 120A may maintain original nanocrystal characteristics without exposure to a chemical solution during the process, and accordingly, be used as a uniform and good light-emitting diode without chemical degradation.

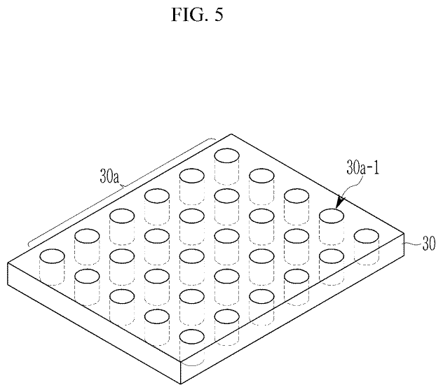

Hereinafter, referring to FIGS. 5 to 8 together with FIG. 1, a method of forming the microstructure array 120A on the first substrate 110 will be described.

FIGS. 5 to 8 are schematic views sequentially showing an example of a method for manufacturing the microstructure array of FIG. 1.

For example, each microstructure 120 of the microstructure array 120A may include perovskite nanocrystals and optionally, further include the hydrophilic polymer, the ionic liquid, and the ligand.

First, referring to FIG. 5, a patterned mold 30 for forming the microstructure array 120A is prepared. The patterned mold 30 includes a concave micropattern array 30a in which a plurality of concave micropatterns 30a-1 are randomly arranged in a predetermined direction. The concave micropatterns 30a-1 may have an empty space inside, and the empty space may be a region where a perovskite precursor solution to be described later is confined to form the microstructure 120.

The shape and size of the concave micropattern 30a-1 may be determined according to the microstructure 120 to be formed, and for example, the shape and size of the concave micropattern 30a-1 may be designed to be substantially the same as the shape and size of the microstructure 120 to be formed. For example, the planar shape of the concave micropattern 30a-1 may be a polygon such as a square, rectangle, hexagon or octagon, a circular or elliptical shape, but is not limited thereto. For example, the size of the concave micropattern 30a-1 may be less than about 100 μm, within the above range, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 15 μm, less than or equal to about 10 μm, or less than or equal to about 7 μm, within the above range, about 0.01 μm to about 80 μm, about 0.01 μm to about 70 μm, about 0.01 μm to about 60 μm, about 0.01 μm to about 50 μm, about 0.01 μm to about 40 μm, about 0.01 μm to about 30 μm, about 0.01 μm to about 20 μm, about 0.01 μm to about 15 μm, about 0.01 μm to about 10 μm, or about 0.01 μm to about 7 μm, about 0.1 μm to about 80 μm, about 0.1 μm to about 70 μm, about 0.1 μm to about 60 μm, about 0.1 μm to about 50 μm, about 0.1 μm to about 40 μm, about 0.1 μm to about 30 μm, about 0.1 μm to about 20 μm, about 0.1 μm to about 15 μm, about 0.1 μm to about 10 μm, or about 0.1 μm to about 7 μm. Herein, the size may be width and/or length in a planar shape.

The depth of the concave micropattern 30a-1 may be shallower than the thickness of the mold 30, for example, the depth of the concave micropattern 30a-1 may be about 0.1 to about 0.9 times, about 0.1 to about 0.7 times, or about 0.1 to about 0.5 times the thickness of the mold 30, but is not limited thereto.

Next, a perovskite precursor solution is prepared. The perovskite precursor solution may include a perovskite precursor, and optionally a hydrophilic polymer, an ionic liquid, and/or a ligand.

The perovskite precursor solution may be prepared, for example, by blending cations and anions in a solvent. At this time, the perovskite precursor solution may be prepared by separately preparing a cation solution including a cation and a solvent and an anion solution including an anion and a solvent followed by blending, or by blending the cations and anions in a solvent.

The cation may be supplied in a form of a compound that is capable of supplying, for example a monovalent inorganic cation such as Lit, Nat, K⁺, Rb⁺, and Cs⁺; a monovalent organic cation such as an organic ammonium cation and an organic amino cation; a divalent metal cation including a transition metal, a rare earth element, an alkaline-earth metal, or a combination thereof such as Pb²⁺, Sn²⁺, Ge²⁺, Ga²⁺, In²⁺, Al²⁺, Sb²⁺, Bi²⁺, and PO²⁺; or a combination thereof. The anion may be supplied in a form of a compound that is capable of supplying, for example, a halide anion. For example, the monovalent organic cation may be alkylammonium, arylammonium, arylalkylammonium, alkylamidinium, arylamidinium, arylalkylamidinium, or a combination thereof, such as methylammonium, formamidinium, or phenylammonium, n-butyl ammonium, 2-phenylmethylammonium, or 2-phenylethylammonium, CH₃NH₃, HC(NH₂)₂, C₄H₉NH₃, C₆H₅CH₂NH₃, C₆H₅C₂H₄NH₃, C₆H₁₃NH₃, or a combination thereof, but is not limited thereto. The divalent metal cation may be, for example, Pb²⁺ or Sn²⁺, and the halide anion may be, for example, F⁻, Cl⁻, Br⁻, or I⁻. The hydrophilic polymer and ligand are as described above.

The solvent is not particularly limited as long as it can dissolve or disperse the aforementioned components. The solvent may be, for example, an organic solvent, for example, dimethylformamide, dimethylsulfoxide, or a combination thereof, but is not limited thereto.

The perovskite precursor, the hydrophilic polymer (or ionic liquid), the ligand, and the solvent may be included in amounts of about 5 to about 50 wt %, about 1 to about 30 wt %, about 0.001 to 10 wt %, and a balance amount, respectively, based on a total content of the perovskite precursor solution.

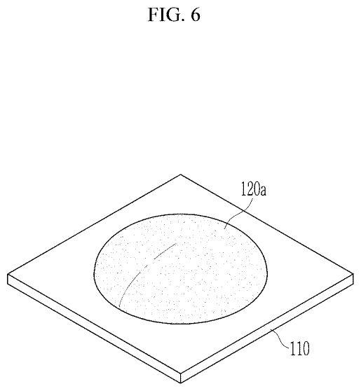

Referring to FIG. 6, a perovskite precursor solution 120a is coated on the first substrate 110. The first substrate 110 may include PDMS modified to be hydrophilic as described above, and may be modified into a hydrophilic surface by performing plasma treatment, such as O₂ plasma, before applying the perovskite precursor solution 120a. The O₂ plasma treatment may be performed, for example, at about 5 W to about 80 W for about 30 seconds to about 30 minutes, or within the above range, at about 10 W to about 50 W for about 1 minute to about 20 minutes, or at about 10 W to about 30 W for about 1 minute to about 10 minutes, but is not limited thereto.

The perovskite precursor solution 120a may be applied onto the hydrophilically modified first substrate 110 by a solution process, such as spin coating, slit coating, inkjet coating, nozzle printing, spraying, dropping, and/or doctor blade coating, but not limited thereto.

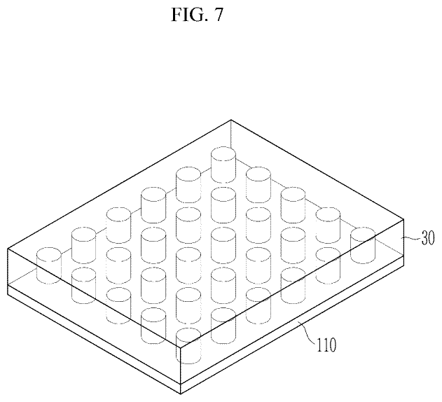

Next, referring to FIG. 7, the patterned mold 30 described above is disposed on the perovskite precursor solution 120a and pressurized. Accordingly, the perovskite precursor solution 120a may be confined in each concave micropattern 30a-1. At this time, as described above, due to the relatively high surface energy and relatively low contact angle of the first substrate 110, the wettability of the perovskite precursor solution 120a for the first substrate 110 may be increased, so that the perovskite precursor solution 120a may be widely spread in the concave micropattern 30a-1 and confined in a shape substantially identical to the planar shape of the concave micropattern 30a-1.

Next, the first substrate 110 is annealed. The annealing may be performed, for example, at a temperature of about 50 to about 200° C. for about 1 minute to about 10 hours, but is not limited thereto. Accordingly, the solvent may be removed from the perovskite precursor solution 120a, and a pattern including perovskite nanocrystals grown from the perovskite precursor and optionally the hydrophilic polymer, the ionic liquid, and/or the ligand may be obtained.

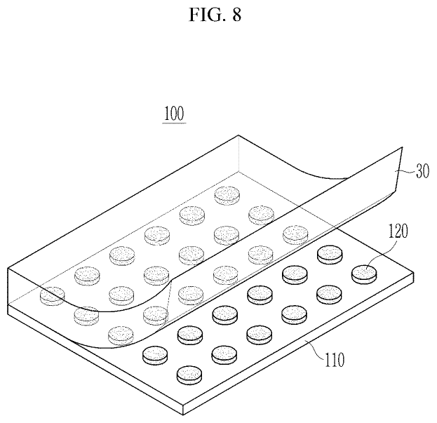

Referring to FIG. 8 together with FIG. 1, the plurality of microstructures 120 including perovskite nanocrystals and optionally the hydrophilic polymer, the ionic liquid, and/or the ligand may be obtained by removing the mold 30 from the first substrate 110.

The microstructure 120 may be substantially the same size as the concave micropattern 30a-1 of the mold 30 or may be smaller than the size of the concave micropattern 30a-1 due to shrinkage caused by heat treatment, etc. Referring to FIG. 1, the plurality of microstructures 120 may be arranged to form a microstructure array 120A.

In this way, the microstructure array 120A may use a mold 30 with concave micropatterns 30a-1 to define in advance a predetermined region (e.g., a region of a sub-pixel of a micro light-emitting diode described later) where the microstructures 120 are to be formed, and the perovskite precursor solution is supplied to this predetermined region and crystallized to effectively precipitate perovskite nanocrystals with a sub-micrometer crystal size. Accordingly, the process may be simplified by simultaneously performing perovskite crystallization and micropattern formation, compared to the conventional method of performing the perovskite crystallization and micropattern formation separately.

Another example of a method for manufacturing a microstructure array according to an embodiment is described with reference to the drawings. This example may realize multi-color luminescence by forming an array of a plurality of microstructures emitting light of different wavelength regions on a single substrate.

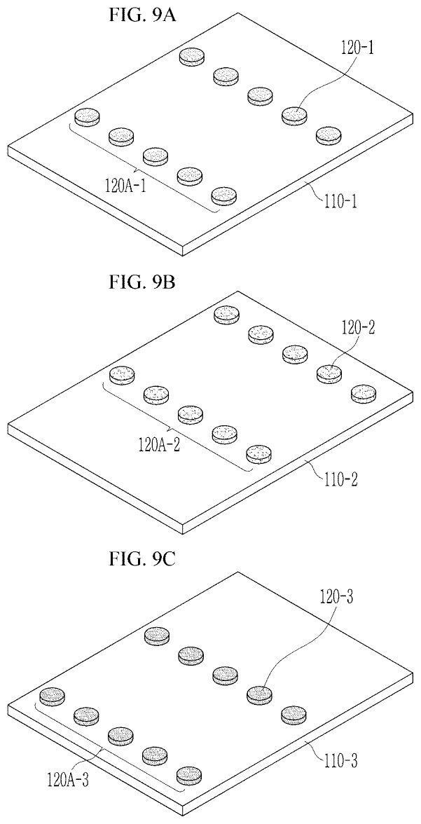

FIGS. 9 to 16 are schematic views sequentially showing another example of a method for manufacturing a microstructure array according to an embodiment.

Referring to FIGS. 9A to 9C, a first microstructure array 120-1A is formed on a first substrate 110-1 in which a plurality of first microstructures 120-1 including nanocrystals configured to emit light in a first wavelength region, which is one of a red wavelength region, a green wavelength region, and a blue wavelength region, are arranged (FIG. 9A), a second microstructure array 120-2A is formed on a first substrate 110-2 in which a plurality of second microstructures 120-2 including nanocrystals configured to emit light in a second wavelength region, which is one of a red wavelength region, a green wavelength region, and a blue wavelength region, are arranged (FIG. 9B), and a third microstructure array 120-3A is formed on a first substrate 110-3 in which a plurality of third microstructures 120-3 including nanocrystals configured to emit light in a third wavelength region, which is one of a red wavelength region, a green wavelength region, and a blue wavelength region, are arranged (FIG. 9C). The first, second, and third wavelength regions may be different from each other, for example, the first wavelength region may be a red wavelength region, the second wavelength region may be a green wavelength region, and the third wavelength region may be a blue wavelength region.

The first substrates 110-1, 110-2, and 110-3 may be different substrates, and each may include PDMS, similar to the first substrate 110 described above. For example, the first substrates 110-1, 110-2, and 110-3 may include PDMS modified to be hydrophilic by plasma treatment such as O₂ plasma. The O₂ plasma treatment of the first substrates 110-1, 110-2, and 110-3 may be performed, for example, at about 5 W to about 80 W for about 30 seconds to about 30 minutes, or within the above range, at about 10 W to about 50 W for about 1 minute to about 20 minutes, or at about 10 W to about 30 W for about 1 minute to about 10 minutes, but is not limited thereto.

The first, second, and third microstructures 120-1, 120-2, and 120-3 may be island-shaped light-emitters with a size of several to several tens of micrometers configured to emit light in the first, second and third wavelength regions, respectively, and may be, for example, less than about 100 μm, within the above range, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 15 μm, less than or equal to about 10 μm, or less than or equal to about 7 μm, and within the above range, and within the above range, greater than or equal to about 0.01 μm and less than about 100 μm, about 0.01 μm to about 80 μm, about 0.01 μm to about 70 μm, about 0.01 μm to about 60 μm, about 0.01 μm to about 50 μm, about 0.01 μm to about 40 μm, about 0.01 μm to about 30 μm, about 0.01 μm to about 20 μm, about 0.01 μm to about 15 μm, about 0.01 μm to about 10 μm, about 0.01 μm to about 7 μm, greater than or equal to about 0.1 μm and less than about 100 μm, about 0.1 μm to about 80 μm, about 0.1 μm to about 70 μm, about 0.1 μm to about 60 μm, about 0.1 μm to about 50 μm, about 0.1 μm to about 40 μm, about 0.1 μm to about 30 μm, about 0.1 μm to about 20 μm, about 0.1 μm to about 15 μm, about 0.1 μm to about 10 μm or about 0.1 μm to about 7 μm.

For example, the first, second, and third microstructures 120-1, 120-2, and 120-3 may be island-shaped light-emitters with a width and length of less than or equal to about 80 μm. For example, the first, second, and third microstructures 120-1, 120-2, and 120-3 may be island-shaped light-emitters with a width and length of less than or equal to about 50 μm. For example, the first, second, and third microstructures 120-1, 120-2, and 120-3 may be island-shaped light-emitters with a width and length of less than or equal to about 30 μm. For example, the first, second, and third microstructures 120-1, 120-2, and 120-3 may be island-shaped light-emitters with a width and length of less than or equal to about 20 μm. For example, the first, second, and third microstructures 120-1, 120-2, and 120-3 may be island-shaped light-emitters with a width and length of less than or equal to about 10 μm.

For example, the nanocrystals configured to emit light in the first, second, or third wavelength region may be perovskite nanocrystals, quantum dot nanocrystals, or a combination thereof, synthesized from a precursor solution including a polar solvent.

For example, the first, second, and third microstructures 120-1, 120-2, and 120-3 may include perovskite nanocrystals configured to emit light in the first, second, and third wavelength regions. The perovskite nanocrystals may have a sub-micrometer crystal size, for example, the average crystal size of the perovskite nanocrystals may be less than or equal to about 800 nm, less than or equal to about 600 nm, less than or equal to about 500 nm, less than or equal to about 300 nm, less than or equal to about 200 nm, less than or equal to about 150 nm, less than or equal to about 100 nm, less than or equal to about 80 nm, or less than or equal to about 50 nm, and within the above range, may be about 2 nm to about 800 nm, about 2 nm to about 600 nm, about 2 nm to about 500 nm, about 2 nm to about 300 nm, about 2 nm to about 200 nm, from 2 nm to 150 nm, about 2 nm to about 100 nm, about 2 nm to about 80 nm, or about 2 nm to about 50 nm.

The perovskite nanocrystals included in the first, second, and third microstructures 120-1, 120-2, and 120-3 may have a relatively uniform crystal size, and for example, a deviation of the crystal size of the perovskite nanocrystals included in the first, second, and third microstructures 120-1, 120-2, and 120-3 may be less than or equal to about 50%, less than or equal to about 40%, less than or equal to about 30%, less than or equal to about 20%, or less than or equal to about 10% of the average crystal size.

For example, the first, second, and third microstructures 120-1, 120-2, and 120-3 may be formed according to the above-described method, and may further include the hydrophilic polymer, the ionic salt, and/or the ligand bound to or coordinated to the surface of the perovskite nanocrystals, in addition to the perovskite nanocrystals. The hydrophilic polymer and ligand are as described above.

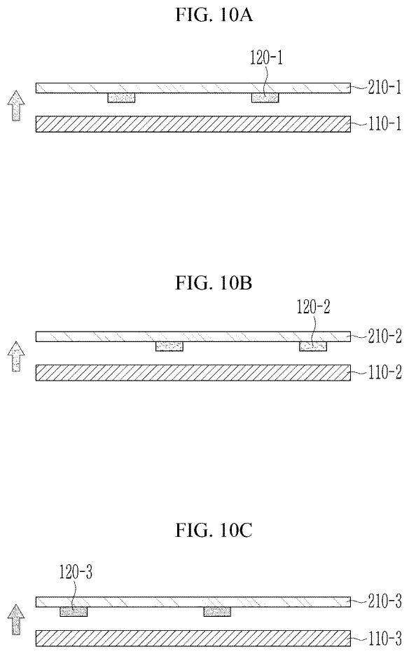

Referring to FIGS. 10A to 10C, a second substrates 210-1, 210-2, and 210-3 is disposed on the plurality of first, second, or third microstructures 120-1, 120-2, and 120-3, respectively, and contact the second substrates 210-1, 210-2, and 210-3 with the plurality of first, second, or third microstructures 120-1, 120-2, and 120-3 to pick up the plurality of first, second, or third microstructures 120-1, 120-2, and 120-3 from the first substrates 110-1, 110-2, and 110-3, respectively.

The second substrates 210-1, 210-2, and 210-3 may be a transfer substrate for picking up the plurality of first, second, and third microstructures 120-1, 120-2, and 120-3 from the first substrates 110-1, 110-2, and 110-3 and transferring the plurality of first, second, and third microstructures 120-1, 120-2, and 120-3 onto third substrates 310-1, 310-2, and 310-3 to be described later.

The second substrates 210-1, 210-2, and 210-3 may be different substrates, and may each include PDMS, similar to the second substrate 210 described above. For example, the second substrates 210-1, 210-2, and 210-3 may include PDMS modified to be hydrophilic by a process such as O₂ plasma treatment, and in the step of contacting the second substrates 210-1, 210-2, and 210-3 with the plurality of first, second, and third microstructures 120-1, 120-2, and 120-3 and picking up the plurality of first, second, and third microstructures 120-1, 120-2, and 120-3 from the first substrates 110-1, 110-2, and 110-3, the surface energy of the second substrates 210-1, 210-2, and 210-3 may be higher than the surface energy of the first substrates 110-1, 110-2, and 110-3. Accordingly, the plurality of first, second, and third microstructures 120-1, 120-2, and 120-3 may be easily separated from the first substrates 110-1, 110-2, and 110-3 and adhered onto the second substrates 210-1, 210-2, and 210-3. For example, the second substrates 210-1, 210-2, and 210-3 may have a relatively low contact angle (water contact angle) of about 0 to about 20 degrees.

For example, to recover the hydrophobicity of the surface of the first substrates 110-1, 110-2, and 110-3, the surface may be left alone until the hydrophilicity disappears, or a separate surface energy reduction treatment may be performed. The surface energy reduction treatment may be, for example, annealing, and may be performed at, for example, about 50 to about 200° C. for about 1 to about 60 minutes, or within the above range, at about 70 to about 150° C. for about 1 to about 40 minutes, or at about 90 to about 110° C. for about 5 to about 15 minutes, but is not limited thereto. A surface contact angle (water contact angle) of the first substrates 110-1, 110-2, and 110-3 subjected to hydrophobic recovery may be about 25 degrees to about 150 degrees.

In this way, the surface energies of the first substrates 110-1, 110-2, and 110-3 and the second substrates 210-1, 210-2, and 210-3 are controlled by recovering the hydrophobicity of the surface of the first substrates 110-1, 110-2, and 110-3 and modifying the hydrophilicity of the surface of the second substrates 210-1, 210-2, and 210-3, so that the plurality of first, second, and third microstructures 120-1, 120-2, and 120-3 may be easily separated from the first substrates 110-1, 110-2, and 110-3 and effectively picked up by closely contacting the second substrates 210-1, 210-2, and 210-3.

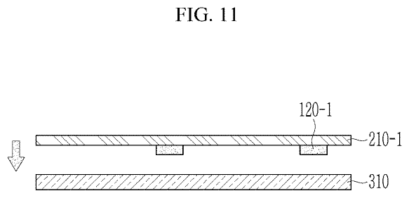

Referring to FIG. 11, the second substrate 210-1 with the plurality of first microstructures 120-1 is disposed on a third substrate 310 to face each other and contact with each other to transfer the plurality of first microstructures 120-1 from the second substrate 210-1 to the third substrate 310.

The third substrate 310 may include, for example, an inorganic material such as glass; an organic material such as polycarbonate, polymethyl methacrylate, polyethylene terephthalate, polyethylene naphthalate, polyamide, polyether sulfone or a combination thereof; a metal plate and/or a silicon wafer. The third substrate 310 may be a final substrate on which the first, second, and third microstructure arrays 120-1A, 120-2A, and 120-3A are arranged, and may be a substrate of a micro light-emitting diode described later.

When transferring the plurality of first microstructures 120-1 from the second substrate 210-1 to the third substrate 310, the surface energy of the third substrate 310 may be higher than the surface energy of the second substrate 210-1, and thus, the plurality of first microstructures 120-1 may be easily separated from the second substrate 210-1 and adhered to the third substrate 310.

To this end, before transferring the plurality of first microstructures 120-1, the surface of the second substrate 210-1 modified to be hydrophilic may be recovered to hydrophobicity. For example, to recover the hydrophobicity of the surface of the second substrate 210-1, the surface may be left alone until the hydrophilicity disappears, or a separate surface energy reduction treatment such as annealing may be performed. The annealing for reducing surface energy of the second substrate 210-1 may be performed at about 25 to about 90° C. for about 5 minutes to about 2 hours, and within the above range, may be performed at about 25 to about 70° C. for about 5 minutes to about 90 minutes or at about 25 to about 50° C. for about 5 minutes to about 60 minutes, but is not limited thereto. The surface energy of the second substrate 210-1 subjected to hydrophobic recovery may be lowered again and have a surface contact angle (water contact angle) of about 25 degrees to about 150 degrees.

For example, an electrode or a stack of an electrode and a charge auxiliary layer may be formed on the third substrate 310. The electrode may include a conductive metal oxide, such as zinc oxide, indium oxide, tin oxide, indium tin oxide (ITO), indium zinc oxide (IZO) or fluorine-doped tin oxide, or a thin single-layer or multi-layer metal film, and the charge auxiliary layer may be, for example, a hole injection layer, a hole transport layer, an electron blocking layer, an electron injection layer, an electron transport layer, and/or a hole blocking layer. To this end, before transferring the microstructure array 120A onto the third substrate 310, the electrode or the stack of the electrode and the charge auxiliary layer may be formed on the third substrate 310, and the surface energy of the electrode or the stack of the electrode and the charge auxiliary layer may be higher than the surface energy of the second substrate 210. For example, the surface contact angle of the electrode or the surface contact angle of the stack of the electrode and the charge auxiliary layer may be, for example, 0 to about 20 degrees, and within the above range may be 0 to about 15 degrees.

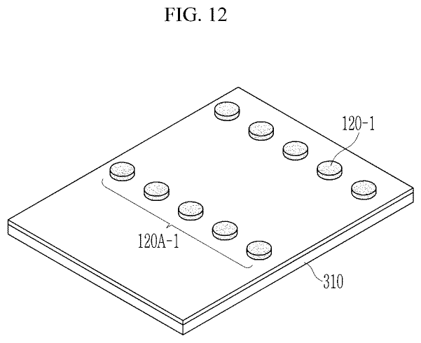

Referring to FIG. 12, the second substrate 210-1 is removed and the first microstructure array 120A-1 in which the plurality of first microstructures 120-1 are arranged is formed on the third substrate 310.

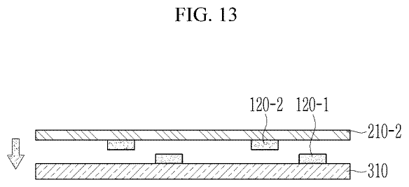

Referring to FIG. 13, the second substrate 210-2 with the plurality of second microstructures 120-2 is disposed on the third substrate 310 to face each other and contact with each other to transfer the plurality of second microstructures 120-2 from the second substrate 210-2 to a third substrate 310 (or an electrode or a stack of an electrode and a charge auxiliary layer on the third substrate 310).

When transferring the plurality of second microstructures 120-2 from a second substrate 210-2 to the third substrate 310 (or the electrode or the stack of the electrode and the charge auxiliary layer on the third substrate 310), the surface energy of the third substrate 310 (or the electrode or the stack of the electrode and the charge auxiliary layer on the third substrate 310) may be higher than the surface energy of the second substrate 210-2, and accordingly, the plurality of second microstructures 120-2 may be easily separated from the second substrate 210-2 and adhered to the third substrate 310 (or the electrode or the stack of the electrode and the charge auxiliary layer on the third substrate 310).

To this end, before transferring the second microstructure array 120A-2, the surface of the second substrate 210-2 modified to be hydrophilic may be recovered to hydrophobicity. For example, to recover the hydrophobicity of the surface of the second substrate 210-2, the surface may be left alone until the hydrophilicity disappears, or a separate surface energy reduction treatment such as annealing may be performed. The annealing for reducing the surface energy of the second substrate 210-2 may be performed, for example, at about 25 to about 90° C. for about 5 minutes to about 2 hours, or within the above range, may be performed at about 25 to about 70° C. for about 5 minutes to about 90 minutes or at about 25 to about 50° C. for about 5 minutes to about 60 minutes, but is not limited thereto. The surface energy of the second substrate 210-2 subjected to hydrophobic recovery may be lowered again and have a surface contact angle (water contact angle) of about 25 degrees to about 150 degrees.

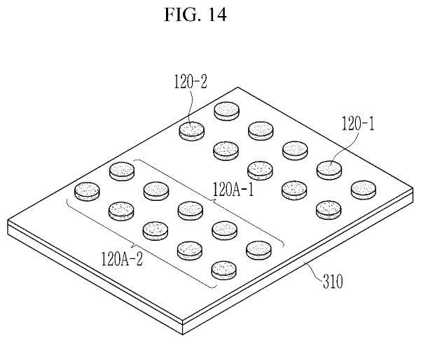

Referring to FIG. 14, the second substrate 210-2 is removed and the second microstructure array 120A-2 in which the plurality of second microstructures 120-2 are arranged is formed on the third substrate 310 (or an electrode or an electrode/charge auxiliary layer stack formed on the third substrate 310).

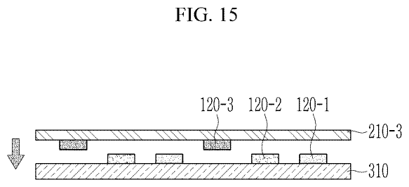

Subsequently, referring to FIG. 15, the second substrate 210-3 with the third microstructure array 120A-3 is disposed on the third substrate 310 (or an electrode or an electrode/charge auxiliary layer stack on the third substrate 310) to face each other and contact the plurality of third microstructures 120-3 with the third substrate 310 to transfer the plurality of third microstructures 120-3 from the second substrate 210-3 to the third substrate 310.

When the plurality of third microstructures 120-3 are transferred from the second substrate 210-3 to the third substrate 310, the third substrate 310 (or an electrode or an electrode/charge auxiliary layer stack on the third substrate 310) may have higher surface energy than the second substrate 210-3, and accordingly, the plurality of third microstructures 120-3 may be easily separated from the second substrate 210-3 and adhered onto the third substrate 310 (or an electrode or an electrode/charge auxiliary layer stack on the third substrate 310).

To this end, before transferring the plurality of third microstructure 120-3, the surface of the second substrate 210-3 modified to be hydrophilic may be recovered to hydrophobicity. For example, to recover the hydrophobicity of the surface of the second substrate 210-3, the surface may be left alone until the hydrophilicity disappears, or a separate surface energy reduction treatment such as annealing may be performed. The annealing for reducing the surface energy of the second substrate 210-3 may be performed, for example, at about 25 to about 90° C. for about 5 minutes to about 2 hours, or within the above range, may be performed at about 25 to about 70° C. for about 5 minutes to about 90 minutes or at about 25 to about 50° C. for about 5 minutes to about 60 minutes, but is not limited thereto. The surface energy of the second substrate 210-3 subjected to hydrophobic recovery may be lowered again and have a surface contact angle (water contact angle) of about 25 degrees to about 150 degrees.

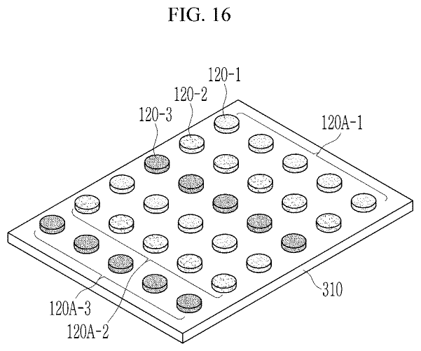

Referring to FIG. 16, the second substrate 210-3 is removed, and the third microstructure array 120A-3 in which the plurality of third microstructures 120-3 are arranged is formed on the third substrate 310 (or an electrode or an electrode/charge auxiliary layer stack formed on the third substrate 310). Accordingly, on the third substrate 310 (or an electrode or an electrode/charge auxiliary layer stack formed on the third substrate 310), the first, second and third microstructure arrays 120A-1, 120A-2, and 120A-3 configured to emit light of different wavelength regions, i.e., first, second, and third wavelength regions, may be arranged side by side.

As described above, when the first, second, and third microstructure arrays 120A-1, 120A-2, and 120A-3 of a micro light-emitting diode are formed, surface energy of the first substrates 110-1, 110-2, and 110-3, the second substrates 210-1, 210-2, and 210-3, and/or the third substrate 310 may be controlled to effectively pick up and transfer the first, second and third microstructure arrays 120A-1, 120A-2, and 120A-3 to form the first, second and third microstructure arrays 120A-1, 120A-2, and 120A-3 configured to emit light in different wavelength regions on the third substrate 310 without exposure to a chemical solution. The first, second and third microstructure arrays 120A-1, 120A-2, and 120A-3 may maintain original nanocrystal characteristics without chemical degradation and accordingly, be used as a uniform and good light-emitting diode.

Herein, the structure that the first, second, and third microstructure arrays 120A-1, 120A-2, and 120A-3 configured to emit light in first, second, and third wavelength regions are arranged is exemplarily described, but the present disclosure is not limited thereto, and at least one of the first, second, and third microstructure arrays 120A-1, 120A-2, and 120A-3 may be formed according to the above-described method.

Hereinafter, a micro light-emitting diode according to an embodiment is described with reference to the drawings.

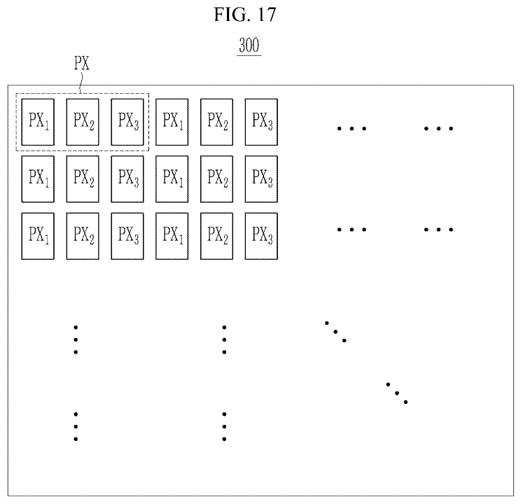

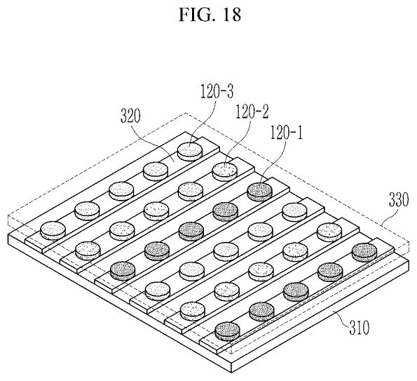

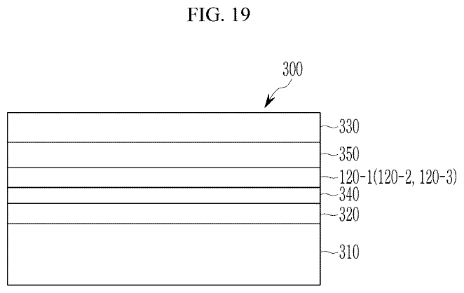

FIG. 17 is a schematic view showing an example of an arrangement of sub-pixels of a micro light-emitting diode according to an embodiment, FIG. 18 is a schematic view showing a micro light-emitting diode according to an embodiment, and FIG. 19 is a cross-sectional view showing one sub-pixel of the micro light-emitting diode of FIG. 18.

Referring to FIG. 17, the micro light-emitting diode 300 according to an embodiment includes a plurality of sub-pixels PX₁, PX₂, and PX₃, and the plurality of sub-pixels PX₁, PX₂, and PX₃ may have a matrix arrangement which is repeatedly arranged along columns and/or rows. The plurality of sub-pixels PX₁, PX₂, and PX₃ displaying different colors may form one pixel PX. For example, a sub-pixel displaying red, a sub-pixel displaying green, and a sub-pixel displaying blue may form one pixel. In FIG. 17, the arrangement of the rectangular sub-pixels PX₁, PX₂, and PX₃ repeatedly arranged along rows and columns is exemplarily illustrated, but the shape and arrangement of the sub-pixels PX₁, PX₂, and PX₃ are not limited thereto.

The sub-pixels PX₁, PX₂, and PX₃ may have an island-shape with a dimension of several to several tens of micrometers, and may have a planar shape of a polygonal shape such as a square, rectangular, hexagonal, or octagonal shape, a circular shape or an elliptical shape, but are not limited thereto. Here, the dimension may be a width and/or a length, and when the planar shape of the sub-pixels PX₁, PX₂, and PX₃ is a circular or elliptical shape, the width may be a diameter or a long diameter.

The dimensions of the sub-pixels PX₁, PX₂, and PX₃ may be substantially the same as the dimension of the aforementioned microstructures 120. For example, the dimensions of the sub-pixels PX₁, PX₂, and PX₃ may be less than about 100 μm, within the above range, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 15 μm, less than or equal to about 10 μm, or less than or equal to about 7 μm, within the above range, about 0.01 μm to about 80 μm, about 0.01 μm to about 70 μm, about 0.01 μm to about 60 μm, about 0.01 μm to about 50 μm, about 0.01 μm to about 40 μm, about 0.01 μm to about 30 μm, about 0.01 μm to about 20 μm, about 0.01 μm to about 15 μm, about 0.01 μm to about 10 μm, or about 0.01 μm to about 7 μm, about 0.1 μm to about 80 μm, about 0.1 μm to about 70 μm, about 0.1 μm to about 60 μm, about 0.1 μm to about 50 μm, about 0.1 μm to about 40 μm, about 0.1 μm to about 30 μm, about 0.1 μm to about 20 μm, about 0.1 μm to about 15 μm, about 0.1 μm to about 10 μm, or about 0.1 μm to about 7 μm.

Referring to FIGS. 18 and 19, a micro light-emitting diode 300 according to an embodiment includes the third substrate 310; a first electrode 320 formed on the third substrate 310; first, second, and third microstructures 120-1, 120-2, and 120-3 formed on the first electrode 320; and a second electrode 330 formed on the first, second, and third microstructures 120-1, 120-2, and 120-3.

The first electrode 320 and the second electrode 330 may face each other, and one of the first electrode 320 and the second electrode 330 may be an anode and the other may be a cathode. For example, the first electrode 320 may be an anode and the second electrode 330 may be a cathode. For example, the first electrode 320 may be a cathode and the second electrode 330 may be an anode. The second electrode 330 may be, for example, a common electrode.

At least one of the first electrode 320 and the second electrode 330 may be a light-transmitting electrode, and the light-transmitting electrode may be made of, for example, zinc oxide, indium oxide, tin oxide, indium tin oxide (ITO), indium zinc oxide (IZO) or a conductive metal oxide such as fluorine-doped tin oxide, or a metal thin layer of a single layer or a multilayer. When one of the first electrode 320 and the second electrode 330 is an opaque electrode, it may be made of an opaque conductor such as aluminum (Al), silver (Ag), or gold (Au).

The first, second, and third microstructures 120-1, 120-2, and 120-3 are disposed between the first electrode 320 and the second electrode 330. The first, second, and third microstructures 120-1, 120-2, and 120-3 may each include nanocrystals including perovskite nanocrystals, quantum dot nanocrystals or a combination thereof, as described above, and optionally include the hydrophilic polymer, the ionic liquid, and/or the ligand. The specific description is as described above, and pick-up and transfer may be performed according to the method described above.

The plurality of first, second, and third microstructures 120-1, 120-2, and 120-3 may be arranged along rows or columns to form a microstructure array, each of which may be configured to emit light of different wavelength regions.

For example, the sub-pixel PX₁ may include the first microstructure 120-1, the sub-pixel PX₂ may include the second microstructure 120-2, and the sub-pixel PX₃ may include the third microstructure 120-3. For example, the first, second, and third wavelength regions may be different wavelength regions of the visible wavelength region, for example, one of the red wavelength region, the green wavelength region, and the blue wavelength region. For example, the first wavelength region may be a red wavelength region, the second wavelength region may be a green wavelength region, and the third wavelength region may be a blue wavelength region. The red wavelength region may have a peak wavelength (λ_{peak,R}) of, for example, more than about 600 nm and less than or equal to about 750 nm, the green wavelength region may have a peak wavelength (λ_{peak,G}) of, for example, about 500 nm to about 600 nm, and the blue wavelength region may have a peak wavelength (λ_{peak,B}) of, for example, greater than or equal to about 380 nm and less than about 500 nm.

A first charge auxiliary layer 340 may be formed between the first electrode 320 and the first, second, and third microstructures 120-1, 120-2, and 120-3, and a second charge auxiliary layer 350 may be formed between the second electrode 330 and the first, second, and third microstructures 120-1, 120-2, and 120-3. The first and second charge auxiliary layers 340 and 350 may be hole auxiliary layers or electron auxiliary layers, and may be, for example, a hole injection layer, a hole transport layer, an electron blocking layer, an electron injection layer, an electron transport layer, and/or a hole blocking layer. The first and second charge auxiliary layers 340 and 350 may include organic, inorganic, and/or organic-inorganic materials. One or both of the first and second charge auxiliary layers 340 and 350 may be omitted.

The micro light-emitting diode 300 may be a bottom emission typed light-emitting diode configured to emit light toward the third substrate 310, a top emission typed light-emitting diode configured to emit light toward the opposite side of the third substrate 310, or a dual emission typed light-emitting diode configured to emit light toward both the third substrate 310 and the opposite side of the third substrate 310.

For example, when the first electrode 320 is a light-transmitting electrode and the second electrode 330 is a non-light-transmitting electrode, the micro light-emitting diode 300 may be the bottom emission typed light-emitting diode.

For example, when the first electrode 320 is an opaque electrode and the second electrode 330 is a light-transmitting electrode, the micro light-emitting diode 300 may be the top emission typed light-emitting diode.

For example, when the first electrode 320 and the second electrode 330 are each light-emitting electrode, the micro light-emitting diode 300 may be the dual emission typed light-emitting diode.

A micro light-emitting diode 300 may be manufactured by being picked up by the first substrates 110-1, 110-2, and 110-3, being picked up by the second substrates 210-1, 210-2, and 210-3, and being transferred to the third substrate 310 according to the manufacturing method of the micro structure array illustrated in FIGS. 9 to 16 described above.

In FIGS. 11 to 16, the third substrate 310 may be a substrate of a micro light-emitting diode, and a first electrode 320 or a stack of the first electrode 320 and the first charge auxiliary layer 340 may be formed on the third substrate 310. The first, second and third microstructures 120-1, 120-2, and 120-3 may be transferred onto a third substrate 310 on which the first electrode 320 or a stack of the first electrode 320 and the first charge auxiliary layer 340 is formed.

The method for manufacturing a micro light-emitting diode 300 may further include forming the second charge auxiliary layer 350 and the second electrode 330 on the first, second, and third micro structures 120-1, 120-2, and 120-3. The second electrode 330 may be a common electrode formed on the whole surface of the first, second and third microstructures 120-1, 120-2, and 120-3. The second charge auxiliary layer 340 may be formed on the whole surface or may be arranged in multiple island or linear shapes depending on the shape of the second electrode 330.

The aforementioned micro light-emitting diode may be applied to various electronic devices requiring light emission, such as display devices or lighting devices, but is not limited thereto.

Hereinafter, the embodiments are illustrated in more detail with reference to examples. However, these examples are exemplary, and the scope of claims is not limited thereto.

### Manufacturing of Mold

### Manufacture Example 1

A p-type Si substrate deposited with 300 nm-thick SiO₂ is washed sequentially with acetone, isopropyl alcohol, and ultrapure water. Subsequently, an epoxy-based photoresist (SU-8, Microchem Corp.) is spin-coated on the Si substrate to form a film. Then, photolithography and etching are sequentially performed on the film to form a plurality of convex micro-patterns in the shape of a hexahedron of 10 μm×10 μm×10 μm (width×length×thickness). Subsequently, an elastomer (Sylgard 184, Dow Corning Corp.) prepared by mixing a polydimethylsiloxane (PDMS) base and a curing agent in a weight ratio of 10:1 is poured onto the convex micropatterns and then, cured at 80° C. for 3 hours. The cured polydimethylsiloxane (PDMS) is separated from the patterned SiO₂ substrate to obtain a polydimethylsiloxane (PDMS) mold having a plurality of concave micropatterns with a square cross-section of 10 μm×10 μm×10 μm (width×length×depth).

### Preparation of Perovskite Precursor Solution

### Preparation Example 1

40 mg of cesium bromide (CsBr, Sigma-Aldrich Co., Ltd.), 60 mg of lead bromide (PbBr₂, Sigma-Aldrich Co., Ltd.), and 18 mg of 1-butyl-3-methylimidazolium tetrafluoroborate (BMIMBF₄, Sigma-Aldrich Co., Ltd.) are dissolved in 1 mL of dimethyl sulfoxide (DMSO, Sigma-Aldrich Co., Ltd.), sealed, and then, sufficiently stirred at 60° C. with a spin bar to prepare a perovskite precursor solution for green light emission.

### Preparation Example 2

21 mg of cesium iodide (CsI, Sigma-Aldrich Co., Ltd.), 17 mg of cesium bromide (CsBr, Sigma-Aldrich Co., Ltd.), 88 mg of lead iodide (PbI₂, Sigma-Aldrich Co., Ltd.), 35 mg of 1-naphthylmethylamine bromide (NMABr, Sigma-Aldrich Co., Ltd.), and 3 mg of potassium bromide (KBr, Sigma-Aldrich Co., Ltd.) are dissolved in 1 mL of dimethyl sulfoxide (DMSO, Sigma-Aldrich Co., Ltd.), sealed, and then, sufficiently stirred at 60° C. with a spin bar to prepare a perovskite precursor solution for red light emission.

### Preparation Example 3

15 mg of cesium chloride (CsCl, Sigma-Aldrich Co., Ltd.), 12 mg of cesium bromide (CsBr, Sigma-Aldrich Co., Ltd.), 55 mg of lead iodide (PbI₂, Sigma-Aldrich Co., Ltd.), 25 mg of 1-phenethylammonium chloride (PEACl, Sigma-Aldrich Co., Ltd.), and 3 mg of 1-butyl-3-methylimidazolium tetrafluoroborate (BMIMBF₄, Sigma-Aldrich Co., Ltd.) are dissolved in 1 mL of dimethyl sulfoxide (DMSO, Sigma-Aldrich Co., Ltd.), sealed, and then, sufficiently stirred at room temperature with a spin bar, preparing a perovskite precursor solution for blue light emission.

### Manufacturing of Microstructure Array I

### Example 1

An elastomer precursor prepared by mixing a PDMS base and a curing agent (Sylgard 184, Dowcorning) in a weight ratio of 20:1 is spin-coated onto a glass substrate, and cured at 80° C. for 3 hours to prepare a PDMS donor substrate (first substrate) and a PDMS transfer substrate (second substrate), respectively.

Subsequently, the PDMS donor substrate is treated with oxygen plasma at 20 W for 3 minutes, while the PDMS mold according to Manufacture Example 1 also is treated with oxygen plasma at 30 W for 3 minutes. Next, the perovskite precursor solution for green light emission according to Preparation Example 1 is spin-coated on the oxygen plasma-treated PDMS donor substrate at 4000 rpm for 40 seconds. Subsequently, the oxygen plasma-treated PDMS mold is placed on the coated perovskite precursor solution for green light emission and then, pressurized and annealed at 90° C. for 10 minutes. Then, the PDMS mold is removed from the PDMS donor substrate to form a plurality of microstructures including crystallized green light-emitting perovskite nanocrystals crystallized from the perovskite precursor solution for green light emission according to Preparation Example 1. The PDMS donor substrate is allowed to stand at room temperature for 30 minutes to recover the oxygen plasma-treated surface to be hydrophobic.

The PDMS transfer substrate is oxygen plasma-treated at 30 W for 3 minutes and then, contact with the plurality of microstructures on the PDMS donor substrate to picked up the plurality of microstructures and transfer them onto an ITO glass substrate (third substrate) coated with PEDOT: PSS (hole auxiliary layer), thereby manufacturing a green light-emitting microstructure array including the green light-emitting perovskite nanocrystals.

### Example 2

A red light-emitting microstructure array including red light-emitting perovskite nanocrystals is manufactured in the same manner as in Example 1 except that the perovskite precursor solution for red light emission according to Preparation Example 2 is used instead of the perovskite precursor solution for green light emission according to Preparation Example 1 and then, annealed at 110° C. for 10 minutes.

### Example 3

A blue light-emitting microstructure array including blue light-emitting perovskite nanocrystals is manufactured in the same manner as in Example 1 except that the perovskite precursor solution for blue light emission according to Preparation Example 3 is used instead of the perovskite precursor solution for green light emission according to Preparation Example 1.

### Evaluation I

The first substrate (PDMS donor substrate) and the second substrate (PDMS transfer substrate) used in Examples are evaluated with respect to changes in surface energy and contact angles after the oxygen plasma treatment.

The contact angles of the first substrate (PDMS donor substrate) and the second substrate (PDMS transfer substrate) are measured immediately after the oxygen plasma treatment under the aforementioned conditions and also, after 30 minutes after the oxygen plasma treatment by dropping ultrapure water and methylene iodide respectively on the first substrates (donor substrate) and the second substrates (transfer substrate) and then, measuring each contact angle on the substrate interface with Phoenix 300 (SEO). The surface energy is calculated by using an Owens-Wendt method. The same method as used above is used to evaluate surface energy and contact angle of an ITO glass substrate (third substrate) coated with PEDOT: PSS.

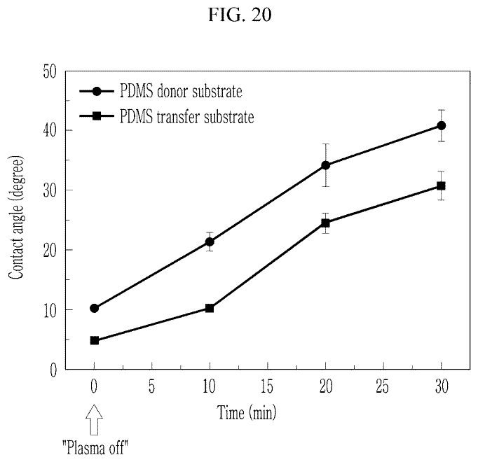

The results are shown in Tables 1 and 2 and FIG. 20.

FIG. 20 is a graph showing changes in the contact angles over time after the oxygen plasma treatment on the first substrate and the second substrate used in the manufacture of the microstructure array according to Example 1.

TABLE 1

| | Immediately after oxygen | | 30 minutes after oxygen | |
|---|---|---|---|---|
| | plasma treatment | | plasma treatment | |
| | Surface | Ultrapure water | Surface | Ultrapure water |
| | energy | contact angle | energy | contact angle |
| | (mJ/m²) | (degrees) | (mJ/m²) | (degrees) |
| first substrate | 74.6 | 10.2 | 58.9 | 40.8 |
| (donor substrate) | | | | |
| second substrate | 75.6 | 4.8 | 65.1 | 30.7 |
| (transfer | | | | |
| substrate) | | | | |

TABLE 2

| | Surface energy | Ultrapure water contact angle |
|---|---|---|
| | (mJ/m²) | (degrees) |
| third substrate | 77.9 | 8 |

Referring to Tables 1 and 2 and FIG. 20, it may be confirmed that hydrophilicity of the first substrate (PDMS donor substrate) and the second substrate (PDMS transfer substrate) used in the manufacture of the microstructure arrays according to Examples is weakened over time after the oxygen plasma treatment, but hydrophobicity thereof is recovered over time after oxygen plasma treatment. Accordingly, it may be expected that effective pick-up and transfer may be achieved by controlling the surface energy of the PDMS substrate.

### Evaluation II

The microstructure arrays according to Examples 1 to 3 are irradiated with an He—Cd laser (λ=325 nm) before and after the transfer to check photoluminescence.

The photoluminescence of the microstructure arrays is evaluated by using a micro-photoluminescence system (Dongwoo Optron Co., Ltd.).

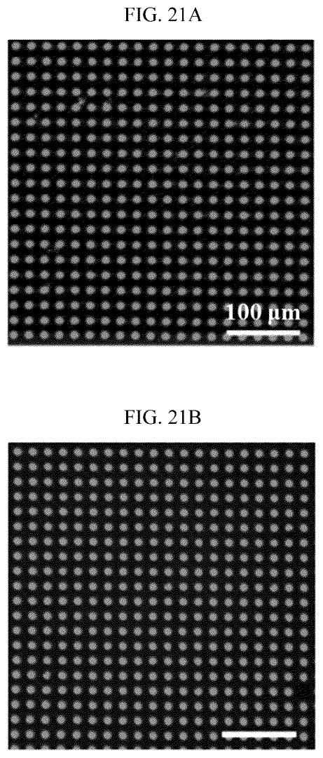

The results are shown in Table 3 and FIGS. 21A, 21B, 22A, 22B, 23A, 23B, and 24.

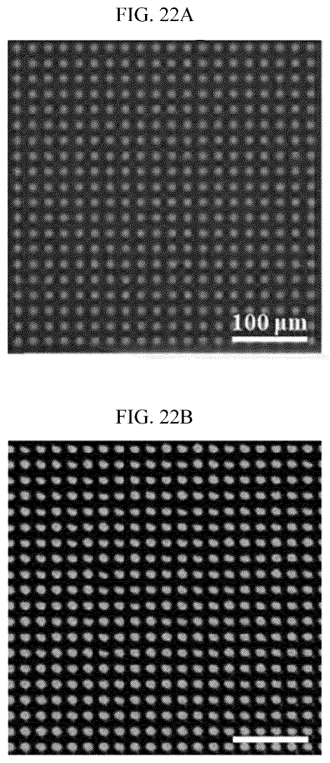

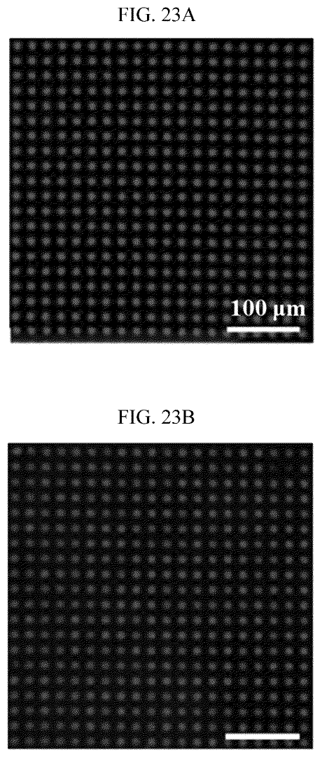

FIG. 21A is a photograph showing the photoluminescence of the microstructure array formed on the first substrate (PDMS donor substrate) in Example 1, FIG. 21B is a photograph showing the photoluminescence of the microstructure array transferred onto the third substrate (ITO glass substrate coated with PEDOT: PSS) in Example 1, FIG. 22A is a photograph showing the photoluminescence of the microstructure array formed on the first substrate (PDMS donor substrate) in Example 2, FIG. 22B is a photograph showing the photoluminescence of the microstructure array transferred onto the third substrate (ITO glass substrate coated with PEDOT: PSS) in Example 2, FIG. 23A is a photograph showing the photoluminescence of the microstructure array formed on the first substrate (PDMS donor substrate) in Example 3, FIG. 23B is a photograph showing the photoluminescence of the microstructure array transferred onto the third substrate (ITO glass substrate coated with PEDOT: PSS) in Example 3, and FIG. 24 shows light emission spectra of the microstructure arrays according to Examples 1 to 3.

TABLE 3

| | Maximum emission wavelength | Full width at half |
|---|---|---|
| | (λₘₐₓ, nm) | maximum (FWHM) (nm) |
| Example 1 | 518.9 | 15 |
| Example 2 | 642.5 | 32.8 |
| Example 3 | 463.8 | 19.6 |

Referring to FIGS. 21 to 23, it may be confirmed that photoluminescence characteristics of the microstructure arrays according to Examples are substantially maintained before and after the transfer.

In addition, referring to Table 3 and FIG. 24, the green, red, and blue light-emitting microstructure arrays according to Examples 1 to 3 exhibit a narrow full width at half maximum (FWHM) in each green, red, and blue wavelength range, which may confirm sufficient luminescence characteristics.

### Manufacturing of Microstructure Array II

### Example 4

As in the method described in Example 1, a plurality of microstructures including green light-emitting perovskite nanocrystals are formed on a PDMS donor substrate and then, picked up and transferred the plurality of microstructures to a PDMS transfer substrate, forming an array of green light-emitting microstructures including the perovskite nanocrystals on an ITO glass substrate (third substrate) coated with PEDOT: PSS (hole auxiliary layer).

Subsequently, as in the method described in Example 2, a plurality of red light-emitting microstructures are formed on a PDMS donor substrate and then, picked up and transferred the plurality of red light-emitting microstructures onto a PDMS transfer substrate, forming an array of red light-emitting microstructures including the red light-emitting perovskite nanocrystals adjacent to the green light-emitting microstructures on the third substrate on which the green light-emitting microstructure array is formed.

Subsequently, as in the method described in Example 3, a plurality of blue light-emitting microstructures are formed on a PDMS donor substrate and then, picked up and transferred the plurality of blue light-emitting microstructures onto a PDMS transfer substrate, forming an array of blue light-emitting microstructures including the blue light-emitting perovskite nanocrystals adjacent to the green and red light-emitting microstructures on the third substrate on which the green and red light-emitting microstructure arrays are formed, manufacturing a multi-color luminescence microstructure array.

### Evaluation III

The multi-color luminescence microstructure array according to Example 4 is evaluated with respect to photoluminescence.

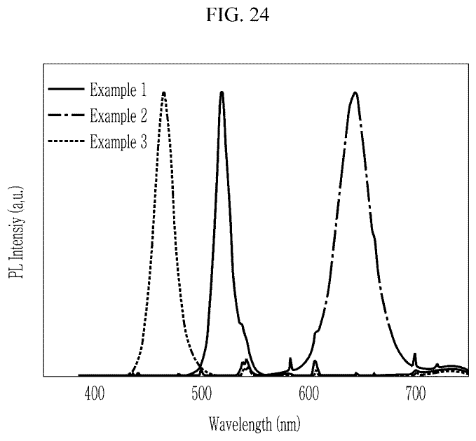

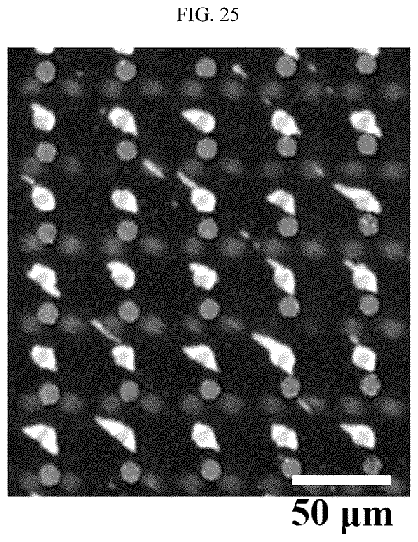

FIG. 25 is a photograph showing the photoluminescence of the green, red, and blue microstructure arrays transferred onto the third substrate (ITO glass substrate coated with PEDOT: PSS) in Example 4.

Referring to FIG. 25, it may be confirmed that the multi-color luminescence microstructure array according to Example 4 exhibits sufficient green, red, and blue emissions.

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A method of manufacturing a microstructure array, the method comprising:
forming a microstructure array in which a plurality of microstructures including nanocrystals are arranged on a first substrate,
contacting a second substrate having a higher surface energy than the first substrate with the microstructure array to pick up the microstructure array from the first substrate, and
transferring the microstructure array from the second substrate to a third substrate having a higher surface energy than the second substrate.

2. The method of claim 1, further comprising performing oxygen plasma treatment on the surface of the second substrate before contacting the second substrate with the microstructure array.

3. The method of claim 2, wherein a surface contact angle of the second substrate subjected to the oxygen plasma treatment is 0 to about 20 degrees.

4. The method of claim 1, further comprising performing a surface energy reduction treatment on the first substrate before contacting the second substrate with the microstructure array.

5. The method of claim 4, wherein a surface contact angle of the first substrate subjected to the surface energy reduction treatment is about 25 degrees to about 150 degrees.

6. The method of claim 1, further comprising performing a surface energy reduction treatment on the second substrate before transferring the microstructure array onto the third substrate.

7. The method of claim 6, wherein a surface contact angle of the second substrate subjected to the surface energy reduction treatment is about 25 to about 150 degrees.

8. The method of claim 1, wherein the first substrate and the second substrate each comprise polydimethylsiloxane.

9. The method of claim 1, wherein the nanocrystals comprise perovskite nanocrystals, quantum dot nanocrystals, or a combination thereof.

10. The method of claim 1, wherein the forming of the microstructure array on the first substrate comprises:
preparing a mold having a plurality of concave micropattern array in which a plurality of concave micropatterns are arranged,
preparing a perovskite precursor solution including a perovskite precursor,
performing the surface of the first substrate with oxygen plasma treatment,
applying the perovskite precursor solution onto the first substrate subjected to oxygen plasma treatment,
placing the mold on the perovskite precursor solution to confine the perovskite precursor solution in the plurality of concave micropatterns,
crystallizing the perovskite precursor in the plurality of concave micropatterns to obtain a plurality of microstructures including perovskite nanocrystals, and
removing the mold to form a microstructure array in which the plurality of microstructures are arranged.

11. The method of claim 1, further comprising forming an electrode or a stack of the electrode and a charge auxiliary layer having a higher surface energy than the second substrate on the third substrate before the transferring of the microstructure array on the third substrate,
wherein the microstructure array is transferred onto the electrode or the stack of the electrode and the charge auxiliary layer.

12. The method of claim 1, wherein the microstructure array is configured to emit light in at least one wavelength region among a red wavelength region, a green wavelength region, or a blue wavelength region.

13. A method of manufacturing a micro light-emitting diode, the method comprising:
preparing a third substrate on which a first electrode or a stack of the first electrode and a first charge auxiliary layer is formed,
transferring a microstructure array onto the first electrode or the stack of the first electrode and the first charge auxiliary layer, and
forming a second electrode or a stack of the second electrode and a second charge auxiliary layer on the microstructure array,
wherein the transferring of the microstructure array comprises
transferring a first microstructure array in which a plurality of first microstructures including nanocrystals configured to emit light of a first wavelength region, which is one of a red wavelength region, a green wavelength region, and a blue wavelength region, are arranged,
transferring a second microstructure array in which a plurality of second microstructures including nanocrystals configured to emit light of a second wavelength region, which is one of a red wavelength region, a green wavelength region, and a blue wavelength region, are arranged, and
transferring a third microstructure array in which a plurality of third microstructures including nanocrystals configured to emit light of a third wavelength region, which is one of a red wavelength region, a green wavelength region, and a blue wavelength region, are arranged, and
at least one of transferring the first, second, and third microstructure arrays comprises
forming a microstructure array in which a plurality of microstructures including nanocrystals are arranged on a first substrate,
contacting a second substrate having a higher surface energy than the first substrate with the microstructure array to pick up the microstructure array from the first substrate, and
transferring the microstructure array from the second substrate onto the first electrode having a higher surface energy than the second substrate or the stack of the first electrode and the first charge auxiliary layer.

14. The method of claim 13, further comprising performing oxygen plasma treatment on the surface of the second substrate before contacting the second substrate with the microstructure array, and
wherein a surface contact angle of the second substrate subjected to the oxygen plasma treatment is 0 to about 20 degrees.

15. The method of claim 13, further comprising performing a surface energy reduction treatment on the first substrate before contacting the second substrate with the microstructure array.

16. The method of claim 15, wherein a surface contact angle of the first substrate subjected to the surface energy reduction treatment is about 25 degrees to about 150 degrees.

17. The method of claim 13, further comprising performing a surface energy reduction treatment on the second substrate before transferring of the microstructure array onto the first electrode or the stack of the first electrode and the first charge auxiliary layer.

18. The method of claim 17, wherein a surface contact angle of the second substrate subjected to the surface energy reduction treatment is about 25 to about 150 degrees.

19. A micro light-emitting diode array manufactured by the method of claim 13.

20. A display device comprising the micro light-emitting diode array according to claim 19.
